(19) United States
(12) Patent Application Publication
(10) Pub. No.: US 2012/0273753 A1
(43) Pub. Date: Nov. 1, 2012

(54) SEMICONDUCTOR LIGHT EMITTING DEVICE

(75) Inventor: Akira Tanaka, Kanagawa-ken (JP)

(73) Assignee: KABUSHIKI KAISHA TOSHIBA, Tokyo (JP)

(21) Appl. No.: 13/234,014

(22) Filed: Sep. 15, 2011

(30) Foreign Application Priority Data
Apr. 26, 2011 (JP) 2011-098090

(51) Int. Cl. H01L 33/04; H01L 33/62

(52) U.S. Cl. 257/13; 257/99; 257/98; 257/E33.006; 257/E33.064

(57) ABSTRACT

According to an embodiment, a semiconductor light emitting device includes a first semiconductor layer of a first conductivity type, a plurality of thin parts thinner than other part being provided in the first semiconductor layer; a second semiconductor layer of a second conductivity type; and a light emitting layer provided between the first semiconductor layer and the second semiconductor layer. A transparent electrode is provided on a surface of the first semiconductor layer; a first electrode is provided on the transparent electrode; and a second electrode contacts a surface of the second semiconductor layer, wherein the second semiconductor layer is provided between the second electrode and the light emitting layer. A current blocking layer is provided for blocking a part of a current path between the transparent electrode and the second electrode, not overlapping the thin part in a planar view parallel to the surface of the second semiconductor layer.

### CROSS-REFERENCE TO RELATED APPLICATIONS

This application is based upon and claims the benefit of priority from Japanese Patent Application No. 2011-98090, filed on Apr. 26, 2011; the entire contents of which are incorporated herein by reference.

### FIELD

Embodiments are generally related to a semiconductor light emitting device.

### BACKGROUND

In recent years, semiconductor light emitting devices have been widely used in fields of lighting equipment, displays, and the like, and have been required to be improved in light output. For example, a light emitting diode (LED), as one of the semiconductor light emitting devices, has on a light emitting face a transparent electrode for current spread and light extraction, and has a reflecting electrode on a side of a major surface opposite to the light emitting face, thereby improving the light output.

Meanwhile, the semiconductor light emitting devices are greatly expected to reduce power consumption. Accordingly, it is desired that the semiconductor light emitting devices are not only improved in light output but also enhanced in light emission efficiency.

### BRIEF DESCRIPTION OF THE DRAWINGS

FIG. 1 is a schematic cross-sectional view illustrating a semiconductor light emitting device according to a first embodiment;

FIGS. 2A and 2B are schematic views illustrating a chip face of the semiconductor light emitting device according to the first embodiment;

FIG. 3 is a schematic view illustrating a characteristic of the semiconductor light emitting device according to the first embodiment;

FIGS. 4A to 6B are schematic cross-sectional views illustrating manufacturing processes of the semiconductor light emitting device according to the first embodiment;

FIG. 7 is a schematic cross-sectional view showing a semiconductor light emitting device according to a second embodiment.

### DETAILED DESCRIPTION

In general, according to an embodiment, a semiconductor light emitting device includes a first semiconductor layer containing an impurity of a first conductivity type, a plurality of thin parts thinner than other part being provided in the first semiconductor layer; a second semiconductor layer of a second conductivity type; and a light emitting layer provided between the first semiconductor layer and the second semiconductor layer. A transparent electrode is provided on a surface of the first semiconductor layer, wherein the first semiconductor layer is provided between the transparent electrode and the light emitting layer; and a first electrode selectively provided on the transparent electrode. A second electrode contacts a surface of the second semiconductor layer, wherein the second semiconductor layer is provided between the second electrode and the light emitting layer; and a current blocking layer is provided for blocking a part of a current path between the transparent electrode and the second electrode, the current blocking layer not overlapping the thin part in a planar view parallel to the surface of the second semiconductor layer.

Embodiments will now be described with reference to the drawings. Throughout the drawings, identical components are marked with identical reference numerals, and detailed descriptions thereof are omitted as appropriate in the specification of the application. In the following embodiments, although a first conductivity type is described as an n-type and a second conductivity type is described as a p-type, the first conductivity type may be a p-type and the second conductivity type may be an n-type.

### First Embodiment

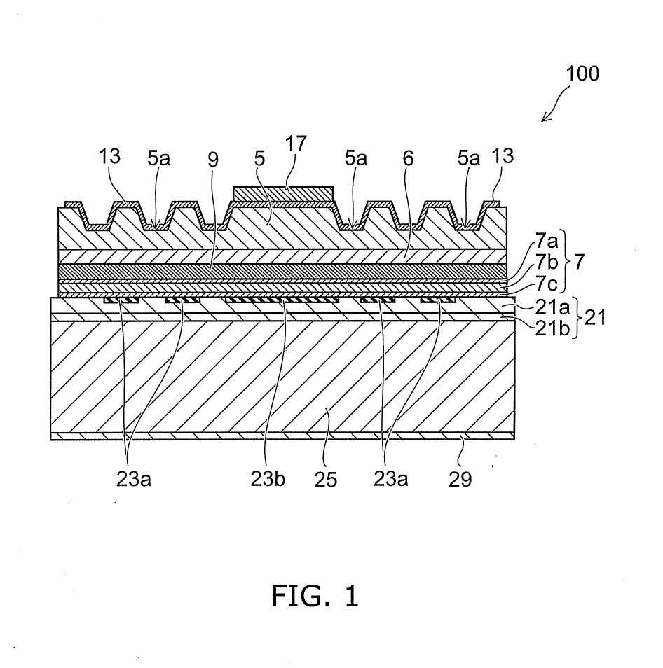

FIG. 1 is a schematic view showing a cross section structure of a semiconductor light emitting device 100 according to a first embodiment. The semiconductor light emitting device 100 is, for example, a blue LED made of a nitride semiconductor.

The semiconductor light emitting device 100 includes an n-type clad layer 5 as a first semiconductor layer, a p-type clad layer 7 as a second semiconductor layer, and a light emitting layer 9 provided between the n-type clad layer 5 and the p-type clad layer 7. Then, each semiconductor layer is provided on a support substrate 25 via a p-electrode 21.

The p-electrode 21 contacts a surface of the p-type clad layer 7 on a side opposite to the light emitting layer 9. The p-type clad layer 7 includes a carrier block layer 7a, a p-type GaN layer 7b, and a p-type contact layer 7c from the light emitting layer 9 side. The carrier block layer 7a includes, for example, a 10 nm-thick p-type Al_{0.15}Ga_{0.85}N layer and suppresses the overflow of electrons from the light emitting layer 9 to the p-type GaN layer 7b. The p-type contact layer 7c is, for example, a p-type GaN layer in which magnesium (Mg) of p-type impurity is doped at a high concentration not less than 5×10¹⁸ cm⁻³, and reduces the contact resistance between the p-electrode 21 and the p-type clad layer 7.

A superlattice layer 6 is provided between the light emitting layer 9 and the n-type clad layer 5. The superlattice layer 6 has the superlattice structure in which a 1 nm-thick n-type In_{0.2}Ga_{0.8}N layer and a 2 nm-thick n-type GaN layer, for example, are alternately stacked, and relieves the crystal strain due to the difference in lattice constant between the n-type clad layer 5 and the light emitting layer 9.

As shown in FIG. 1, the n-type clad layer 5 has a plurality of thin parts 5a thinner than the other part of the n-type clad layer 5. If the thickness of the n-type clad layer 5 is, for example, 2 μm, the thickness of the thin part 5a is not more than 1 μm. Then, a transparent electrode 13 is provided on the surface of the n-type clad layer 5 (that includes the surface of the thin part 5a) on a side opposite to the light emitting layer 9. The transparent electrode 13 includes, for example, a conductive film that transmits visible light, and contains, for example, ITO (Indium Tin Oxide). An n-electrode 17 is selectively provided on the transparent electrode 13.

In the semiconductor light emitting device 100, a drive current flowing from the p-electrode 21 as a second electrode to the n-electrode 17 as a first electrode causes blue light emission in the light emitting layer 9. Then, the light emitted from the light emitting layer 9 passes through the transparent electrode 13 to be released to outside. The p-electrode 21 reflects the light emitted from the light emitting layer 9, in the direction of the n-type clad layer 5. Thereby, the light emission efficiency is improved.

On the other hand, the thin part 5a is provided in the n-type clad layer 5, and configured to increase the density of carriers (electron and hole) injected into the light emitting layer 9 under the thin part 5a. That is, the resistance of the current path from the light emitting layer 9 via the thin part 5a to the transparent electrode 13 is smaller than the resistance of the current path from the light emitting layer 9, via the thick n-type clad layer 5 other than the thin part 5a, to the transparent electrode 13. Accordingly, much of the drive current that flows from the p-electrode 21 to the transparent electrode 13 concentrates in the current path via the thin part 5a, and the carrier density of the light emitting layer 9 under the thin part 5a becomes higher than the carrier density of the other part of the light emitting layer 9.

Furthermore, current blocking layers 23a and 23b are provided between the p-electrode 21 and the p-type clad layer 7. The current blocking layer 23b is provided at the position overlapping the n-electrode 17 in a planar view parallel to the surface of the p-type clad layer 7. Then, the current path between the p-electrode 21 and the n-electrode 17 is blocked, and the current that flows into the light emitting layer 9 under the n-electrode 17 is suppressed.

On the other hand, the current blocking layer 23a is provided at the position not overlapping the thin part 5a in a planar view parallel to the surface of the p-type clad layer 7. The current blocking layer 23a blocks the current path via the n-type clad layer 5 other than the thin part 5a from the p-electrode 21 to the transparent electrode 13, and suppresses the current that flows via the part other than the thin part 5a, of the n-type clad layer 5.

That is, in the semiconductor light emitting device 100 according to the embodiment, by the thin part 5a provided in the n-type clad layer 5, and the current blocking layers 23a and 23b, the drive current is concentrated in the current path via the thin part 5a from the p-electrode 21 to the transparent electrode 13. Thereby, the density of carriers injected into the light emitting layer 9 under the thin part 5a is increased to improve the light emission efficiency.

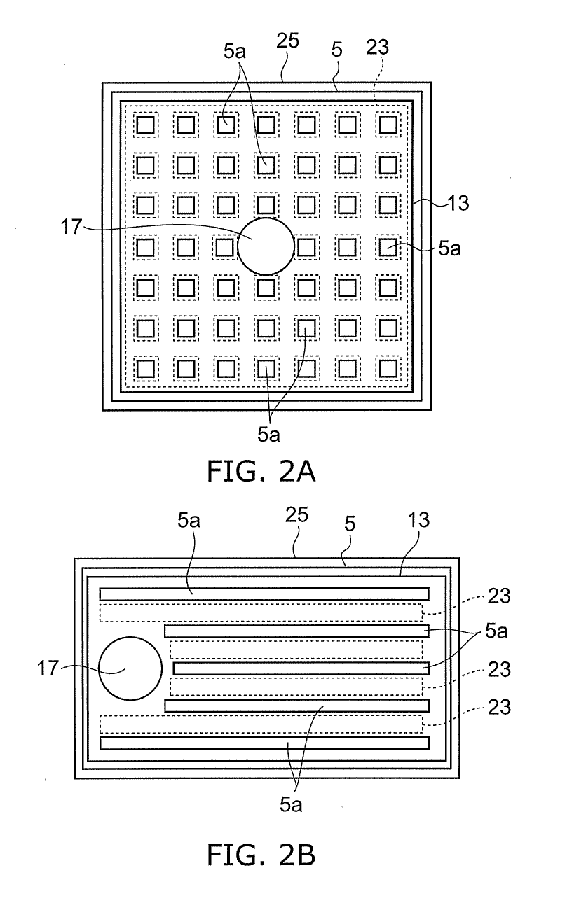

FIGS. 2A and 2B are schematic views illustrating a chip face of the semiconductor light emitting device 100. As shown in FIGS. 2A and 2B, a stacked body including the n-type clad layer 5, the p-type clad layer 7, and the light emitting layer 9 is provided on the support substrate 25, and the transparent electrode 13 is provided on the surface of the n-type clad layer 5.

For example, as shown in FIG. 2A, the plurality of thin parts 5a provided in the n-type clad layer 5 can be formed as a plurality of separated concave parts. The shape is optional, i.e. the shape may be rectangular or circular as shown in FIG. 2A. The distance between adjacent thin parts 5a is preferably not less than the diffusion length of electrons or holes. The distance is preferably a value (2 to 100 μm) at which the thin parts can be separately formed, even when side etching and the like are taken into account in manufacturing process.

Further, as shown in FIG. 2B, the plurality of stripe-shaped thin parts 5a may be evenly provided on the surface of the n-type clad layer 5, excluding the n-electrode 17. Furthermore, a current blocking layer 23 between the p-electrode 21 and the p-type clad layer 7 is provided so as not to overlap the thin part 5a in a planar view parallel to the surface of the p-type clad layer 7.

As shown in FIG. 2A, the current blocking layer 23 is provided surrounding the plurality of thin parts 5a separately provided from one another in the n-type clad layer 5, for example. The current blocking layer 23 includes the part 23b provided under the n-electrode 17 and the part 23a that does not overlap the thin part 5a.

On the other hand, in FIG. 2B, the current blocking layer is provided between the stripe-shaped thin parts 5a. Furthermore, the current blocking layer 23b (see FIG. 1) may be provided under the n-electrode 17.

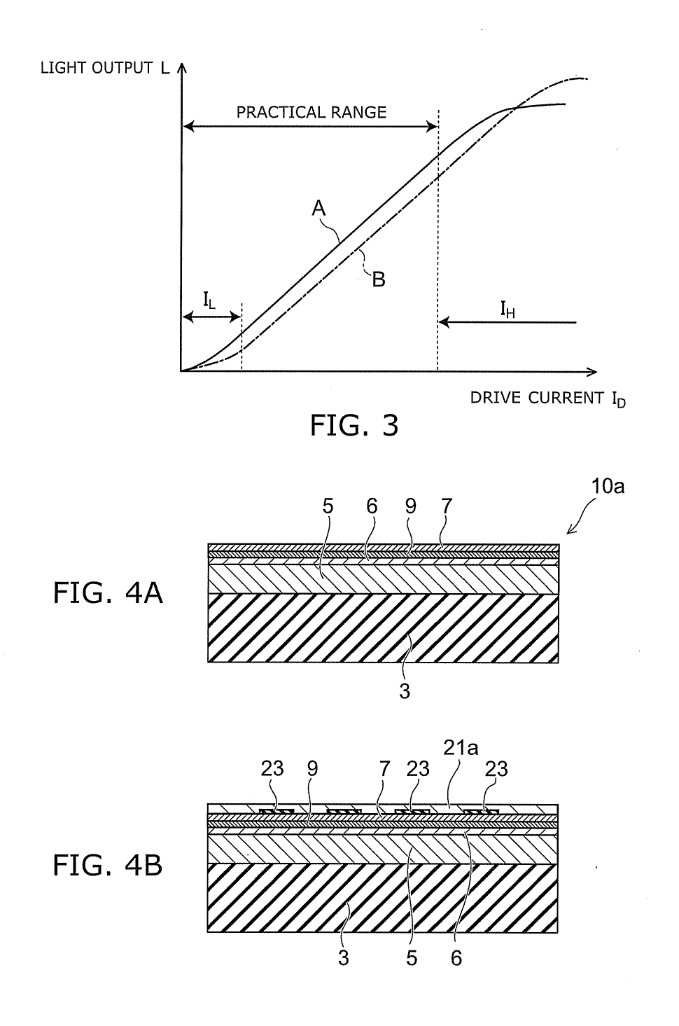

FIG. 3 is a schematic view showing an I-L characteristic of the semiconductor light emitting device 100. The horizontal axis represents the drive current I_{D}, and the vertical axis represents the light output L. A in FIG. 3 denotes a graph showing the I-L characteristic of the semiconductor light emitting device 100. B denotes a graph showing an I-L characteristic of a semiconductor light emitting device (not shown) according to a comparative example. The semiconductor light emitting device according to the comparative example is different from the semiconductor light emitting device 100 in that the thin part 5a is not provided, the thickness of the n-type clad layer 5 is uniform, and the current blocking layer 23a is not provided.

When the transparent electrode 13 is formed on the surface of the n-type clad layer 5 of uniform thickness, the drive current I_{D} spreads in the entire face of the n-type clad layer 5 to be uniformly injected to the light emitting layer 9. Consequently, the entire of the light emitting layer 9 emits light, except for the part under the n-electrode 17 where the current blocking layer 23b is provided. As a result, the I-L characteristic of the graph B is exhibited.

The light output L as shown in the graph B increases monotonically, as the drive current I_{D} increases. However, in a low injection region I_{L} in which the drive current I_{D} is small, the increase rate of the light output L to the drive current I_{D} is low, i.e. the light emission efficiency is low. When the drive current I_{D} flows beyond the low injection region I_{L}, the increase rate of the light output L becomes high, and the light emission efficiency is improved. Furthermore, when the drive current I_{D} is increased to a high injection region I_{H}, the light output L exhibits saturation tendency.

For example, semiconductor light emitting devices are used in the practical range where the drive current ID is smaller than in the high injection region I_{H}, in view of lifetime and controllability.

In contrast, in the I-L characteristic of the semiconductor light emitting device 100 as shown in the graph A, the increase rate of the light output is improved from the low injection region I_{L}, and the light output in the practical range becomes higher than that in the comparative example. This difference is described as below.

In the light emitting layer 9, a part of electrons and holes injected by the drive current I_{D} releases light to recombine and another part of electrons and holes recombines through the non-emissive process that does not release light. For example, an SRH process (Shockley-Read-Hall process) in which recombination is induced via a deep level in a bandgap has been known as non-emissive process. When the number of electrons and holes injected into the light emitting layer 9 is small, such non-emissive recombination occurs at a high rate. Since the number of deep levels that contribute to non-emissive recombination is limited, the rate of emissive recombination becomes high as the number of electrons and holes becomes large, and light emission efficiency is improved. As a result, the I-L characteristic as shown in the graph B is exhibited.

On the other hand, in the semiconductor light emitting device 100, since the drive current I_{D} that flows via the thin part 5a of the n-type clad layer 5 increases, the carrier density of the light emitting layer 9 under the thin part 5a becomes higher than that under the thick part of the n-type clad layer 5. Therefore, the part under the thin part 5a mainly contributes to light emission in the light emitting layer 9.

That is, in the semiconductor light emitting device 100, since a substantial light emitting region is narrowed to the part under the thin part 5a, the carrier density of the light emitting region becomes higher in the low injection region I_{L} than that in the comparative example. Thereby, the rate of non-emissive recombination decreases, and the light emission efficiency is improved in the practical range.

Furthermore, in the high injection region I_{H} where the drive current I_{D} is large, the carrier density of the light emitting layer 9 under the thin part 5a in the semiconductor light emitting device 100 becomes higher than that in the comparative example. Accordingly, the current loss due to the overflow of electrons that flow from the light emitting layer 9 to the p-type clad layer 7, Auger effect, or the like increases, and the saturation tendency of the light output L becomes significant. As a result, the light output L in the high injection region I_{H} becomes lower in the semiconductor light emitting device 100 than that in the comparative example. However, if the light output of the semiconductor light emitting device 100 is higher than that of the comparative example in the practical range, the semiconductor light emitting device 100 may be said to have a higher output characteristic than the comparative example, and the light emission efficiency may be said to be improved.

On the other hand, when excessive current concentrates in the thin part 5a, the saturation tendency of the light output occurs also in the practical range of the drive current. Therefore, as shown in FIGS. 2A and 2B, the thin parts 5a are preferably provided on the entire of the surface of the n-type clad layer 5, excluding the part under the n-electrode 17, or preferably evenly provided on the larger area of the chip surface.

Further, in the semiconductor light emitting device 100, a part of the drive current is preferably flows even in the current path via the part thicker than the thin part 5a, in the n-type clad layer 5, and carriers are preferably injected even in the light emitting layer 9 under the thick part of the n-type clad layer 5. That is, the light emitting layer 9 may becomes an absorber of emitted light, where carrier density is low. On this account, injecting carriers into the light emitting layer 9 under the part thicker than the thin layer part 5a may improve light emission efficiency by suppressing the light absorption. For example, providing the transparent electrode 13 even on the surface of the part thicker than the thin part 5a, of the n-type clad layer 5, preferably injects carriers into the light emitting layer 9 under the thick part.

Furthermore, the transparent electrode 13 is provided inside the outer edge of the n-type clad layer 5. That is, the transparent electrode 13 is not provided on the part along the outer edge of the n-type clad layer 5. For example, surface defects exist at a high density on the side faces of the n-type clad layer 5 and the light emitting layer 9. Consequently, when a drive current is flows in the outer edge of the n-type clad layer 5, non-emissive recombination increases to lower light emission efficiency. Therefore, not providing the transparent electrode 13 in the part along the circumference of the n-type clad layer 5 may suppress the drive current that flows on the side faces of the n-type clad layer 5 and the light emitting layer 9, and prevent the lowering of light emission efficiency.

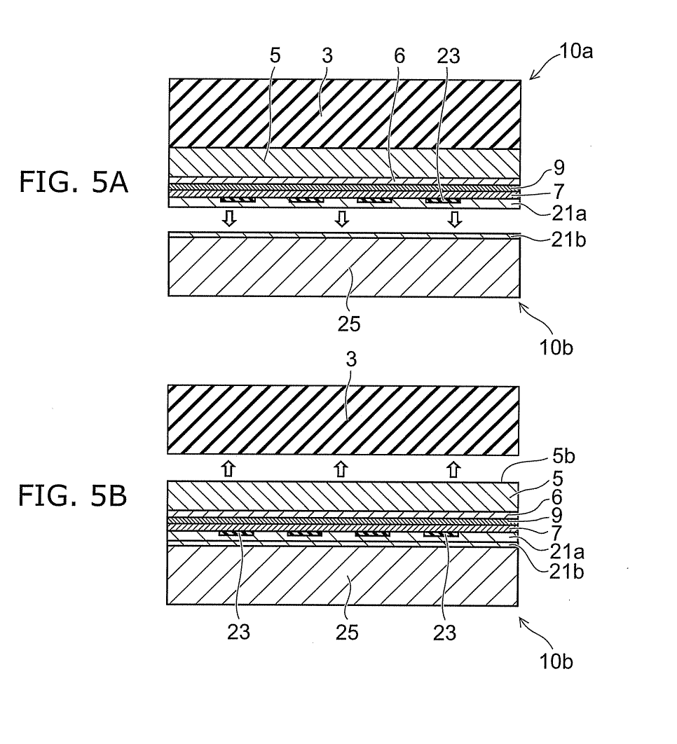

Next, the manufacturing processes of the semiconductor light emitting device 100 will be described with reference to FIGS. 4A to 6B. FIGS. 4A to 6B are schematic views showing cross sections of wafers in each process.

To begin with, a wafer 10a is formed as shown in FIG. 4A, in which the n-type clad layer 5, the superlattice layer 6, the light emitting layer 9, and the p-type clad layer 7 are grown in sequence on a sapphire substrate 3. These layers can be formed using a MOCVD (Metal Organic Chemical Vapor Deposition) method, for example.

For example, an n-type GaN layer is formed as the n-type clad layer 5 with 2.0 μm thick, and the superlattice layer 6 that includes 20 alternate pairs of a 1 nm-thick n-type In_{0.2}Ga_{0.8}N layer and a 2 μm-thick n-type GaN layer is formed on the n-type clad layer 5. Furthermore, a multiple quantum well (MQW) structure that includes eight quantum wells is formed as the light emitting layer 9. The quantum well includes a 2.5 nm-thick well layer that contains In_{0.2}Ga_{0.8}N, and a 10 nm-thick barrier layer that contains In_{0.05}Ga_{0.95}N.

The p-type clad layer 7 formed on the light emitting layer 9 includes, for example, a 10 nm-thick p-type Al_{0.15}Ga_{0.85}N layer, a 40 nm-thick p-type GaN layer, and a 5 nm-thick p-type contact layer in which p-type impurities are doped at a higher concentration, from the light emitting layer 9 side. For example, the concentration in the p-type GaN layer is 5×10¹⁷ cm⁻³, and a p-type GaN layer with a concentration not less than 5×10¹⁸ cm⁻³ is formed as the p-type contact layer.

Next, as shown in FIG. 4B, the current blocking layer 23 and the p-electrode 21a are formed on the p-type clad layer 7. A silicon oxide film (SiO₂ film) can be used as the current blocking layer 23, which is formed using a CVD (Chemical Vapor Deposition) method, for example. A multilayer film in which nickel (Ni), Ag, platinum (Pt), and Au, for example, are stacked in sequence from the p-type clad layer 7 side can be used as the p-electrode 21a.

Next, as shown in FIG. 5A, the wafer 10a and a wafer 10b are bonded. The wafer 10b includes the support substrate 25, and the p-electrode 21b formed on a surface of the support substrate 25. A p-type silicon substrate or a p-type germanium substrate, for example, can be used for the support substrate 25. Au, for example, is used for the p-electrode 21b. Then, as shown in the figure, the p-electrode 21a and the p-electrode 21b are bonded by bringing a surface of the p-electrode 21a into contact with a surface of the p-electrode 21b and applying weight from the back sides of both wafers. The p-electrode 21 includes the combined p-electrode 21a and p-electrode 21b.

Subsequently, for example, YAG laser is irradiated from the back side of the wafer 10a and dissociates a part of the n-type clad layer 5. As shown in FIG. 5B, the sapphire substrate 3 is separated from the n-type clad layer 5.

Next, as shown in FIG. 6A, an etching mask 31 is formed on the surface 5b of the n-type clad layer 5 exposed by separating the sapphire substrate 3. Subsequently, the n-type clad layer 5 is etched using, for example, an RIE (Reactive Ion Etching) method to form the thin part 5a.

Next, as shown in FIG. 6B, the etching mask 31 is removed, and the transparent electrode 13 is formed on the surface of the n-type clad layer 5. An ITO film formed using a sputtering method, for example, is used for the transparent electrode 13. The film thickness of the ITO film is 400 nm, for example. Further, not only an ITO film but also a zinc oxide (ZnO) film, a tin oxide (Sn₂O) film, or the like may be used for the transparent electrode 13.

Subsequently, after the n-electrode 17 (see FIGS. 2A and 2B) is formed on the transparent electrode 13, the semiconductor layers from the n-type clad layer 5 to the p-type clad layer 7 are selectively etched, and a light emitting face 20 is defined. Furthermore, a bonding electrode 29 is formed on the back face of the support substrate 25, and individual chips are diced by cutting the support substrate 25, thereby completing the semiconductor light emitting device 100.

### Second Embodiment

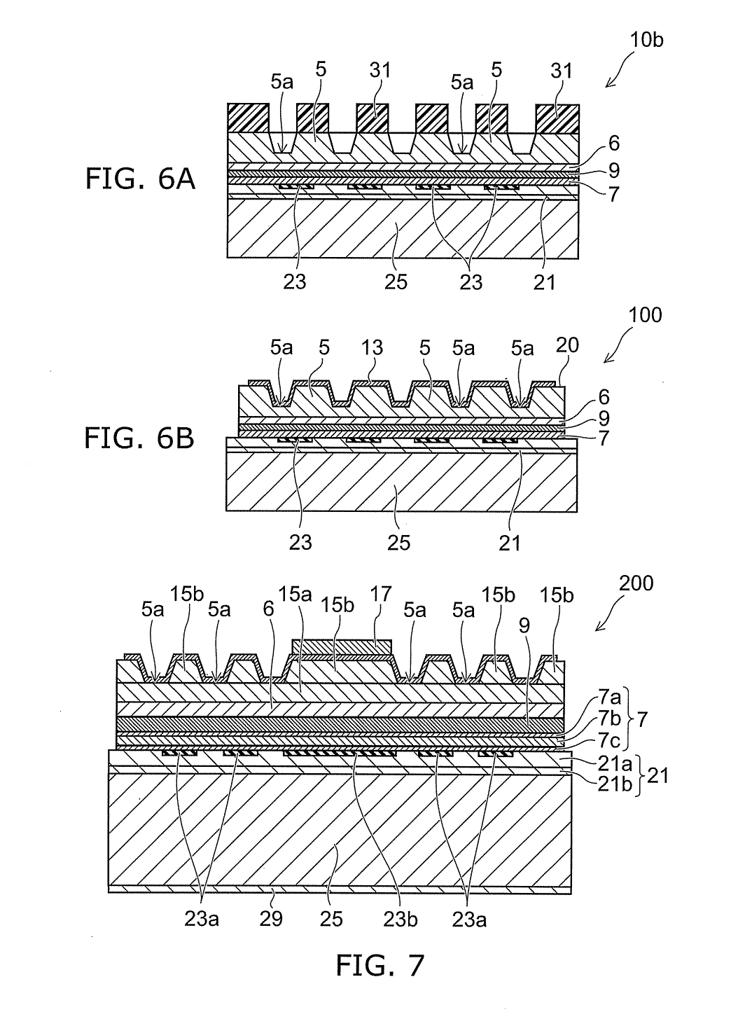

FIG. 7 is a schematic view showing a cross section of a semiconductor light emitting device 200 according to the second embodiment. The semiconductor light emitting device 200 differs from the semiconductor light emitting device 100 in that the n-type clad layer 5 as the first semiconductor layer includes an n-type contact layer 15a provided on a side of the light emitting layer 9, and a high resistance layer 15b provided between the n-type contact layer 15a and the transparent electrode 13 in the semiconductor light emitting device 200.

The transparent electrode 13 contacts the n-type contact layer 15a in the thin part 5a. Further, the transparent electrode 13 also contacts the high resistance layer 15b in the part excluding the thin part 5a, of the n-type clad layer 5.

The n-type contact layer 15a is, for example, a low resistance layer in which silicon (Si) of n-type impurity is doped at a concentration not less than 1×10¹⁷ cm⁻³. The high resistance layer 15b has higher resistivity than the n-type contact layer 15a, and contains n-type impurities lower in concentration than the n-type contact layer 15a. For example, an undoped GaN layer in which an n-type impurity is not consciously doped may be used for the high resistance layer 15b. Further, p-type GaN layer may be used for the high resistance layer 15b, wherein the drive current is blocked by a pn junction provided between the n-type contact layer 15a and the high resistance layer 15b containing a p-type impurity.

In the semiconductor light emitting device 200, the resistance difference between the n-type contact layer 15a and the high resistance layer 15b makes the drive current flow from the p-electrode 21 to the transparent electrode 13 and concentrate into the thin part 5a. Then, the carrier density in the light emitting layer 9 under the thin part 5a is made higher than that in the other part of the light emitting layer 9, and the light emission efficiency can be improved.

Further, if the concentration in the n-type contact layer 15a is low and its layer thickness is large, it is possible to spread the drive current to the light emitting layer 9 side under the high resistance layer 15b, and carriers injected into the part increase. On the other hand, if the concentration in the n-type contact layer 15a is high and its layer thickness is small, the carrier density of the light emitting layer 9 under the thin part 5a becomes high, and carriers injected into the light emitting layer 9 under the high resistance layer 15b decrease.

Therefore, by preferably providing the impurity concentration in the n-type contact layer 15a and its thickness, the drive current is appropriately concentrated in the light emitting layer 9 under the thin part 5a. In addition, by injecting carriers into the light emitting layer 9 under the high resistance layer 15b, the light absorption is suppressed. Thereby, the light emission efficiency can be improved. Furthermore, it is possible to suppress excessive current injection in the light emitting layer 9 under the thin part 5a, and not to cause the saturation of light output in the practical range of drive current.

For example, in GaN-based nitride semiconductors, the difference in resistivity is large between the undoped high resistance layer 15b and the n-type contact layer 15a in which an n-type impurity is intentionally doped. On this account, even in the structure in which the current blocking layers 23a and 23b between the p-electrode 21 and the p-type clad layer 7 are not provided, it is possible to concentrate the drive current in the thin part 5a and to improve the light emission efficiency. That is, it is possible to cause the high resistance layer 15b to function as substitute for the current blocking layers 23a and 23b.

Hereinabove, although the semiconductor light emitting devices made of nitride semiconductors are described as examples in the first and second embodiments, the semiconductor material is not limited to nitride semiconductors. The device may be a light emitting device using, for example, a compound semiconductor such as a GaAs-based or an InP-based compound semiconductor as material.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

The “nitride semiconductor” referred to herein includes group III-V compound semiconductors of BₓIn_{y}Al_{z}Ga_{1-x-y-z}N (0≦x≦1, 0≦y≦1, 0≦z≦1, 0≦x+y+z≦1), and also includes mixed crystals containing a group V element besides N (nitrogen), such as phosphorus (P) and arsenic (As). Furthermore, the “nitride semiconductor” also includes those further containing various elements added to control various material properties such as conductivity type, and those further containing various unintended elements.

What is claimed is:

1. A semiconductor light emitting device comprising:
a first semiconductor layer containing an impurity of a first conductivity type, a plurality of thin parts thinner than other part being provided in the first semiconductor layer;
a second semiconductor layer of a second conductivity type;
a light emitting layer provided between the first semiconductor layer and the second semiconductor layer;
a transparent electrode provided on a surface of the first semiconductor layer, the first semiconductor layer being provided between the transparent electrode and the light emitting layer;
a first electrode selectively provided on the transparent electrode;
a second electrode contacting a surface of the second semiconductor layer, the second semiconductor layer being provided between the second electrode and the light emitting layer; and
a current blocking layer for blocking a part of a current path between the transparent electrode and the second electrode, the current blocking layer not overlapping the thin part in a planar view parallel to the surface of the second semiconductor layer.

2. The device according to claim 1, wherein the current blocking layer is provided between the second semiconductor layer and the second electrode.

3. The device according to claim 1, wherein the current blocking layer overlaps the first electrode in a planar view parallel to the surface of the second semiconductor layer.

4. The device according to claim 1, wherein
the first semiconductor layer includes a contact layer provided on the light emitting layer and a high resistance layer provided between the contact layer and the transparent electrode, and
the transparent electrode contacts the contact layer in the thin part.

5. The device according to claim 4, wherein a concentration of a first conductivity type impurity in the contact layer is higher than a concentration of a first conductivity type impurity in the high resistance layer.

6. The device according to claim 4, wherein the high resistance layer contains a second conductivity type impurity.

7. The device according to claim 1, wherein a thickness of the thin part is not more than one-half of a thickness of the other part.

8. The device according to claim 1, wherein the second electrode reflects light emitted from the light emitting layer in a direction of the first semiconductor layer, and the light is extracted through the transparent electrode to outside.

9. The device according to claim 1, wherein each of the thin parts is included in one of a plurality of concave separately provided in the first semiconductor layer, and a distance between the adjacent thin parts is larger than a diffusion length of electrons or holes.

10. The device according to claim 1, wherein the thin parts are provided in a plurality of stripe-shapes, and a distance between the adjacent thin parts is larger than a diffusion length of electrons or holes.

11. The device according to claim 1, wherein the transparent electrode is provided on an inner side of an outer edge of the first semiconductor layer.

12. The device according to claim 1, wherein the transparent electrode is provided on both of the surface of the thin part and the surface of the other part.

13. The device according to claim 1, wherein the current blocking layer includes a silicon oxide film.

14. The device according to claim 1, wherein the transparent electrode contains at least one of ITO, ZnO, and Sn₂O.

15. The device according to claim 1, wherein a superlattice layer is provided between the light emitting layer and the first semiconductor layer.

16. The device according to claim 1, wherein the second semiconductor layer includes an carrier block layer, a second conductivity type clad layer, and a second conductivity type contact layer, from the light emitting layer side.

17. The device according to claim 1, further comprising a support substrate provided on the second electrode, wherein the second electrode is provided between the support substrate and the second semiconductor layer.

18. A semiconductor light emitting device comprising:
a first semiconductor layer containing an impurity of a first conductivity, a plurality of thin parts thinner than other part being provided in the first semiconductor layer;
a second semiconductor layer of a second conductivity type;
a light emitting layer provided between the first semiconductor layer and the second semiconductor layer;
a transparent electrode provided on a surface of the first semiconductor layer on a side opposite to the light emitting layer;
a first electrode selectively provided on the transparent electrode; and
a second electrode contacting a surface of the second semiconductor layer on a side opposite to the light emitting layer,
wherein the first semiconductor layer includes a contact layer provided on the light emitting layer side, and a high resistance layer provided between the contact layer and the transparent electrode, and
the transparent electrode contacts the contact layer in the thin part.

19. The device according to claim 18, wherein a concentration of a first conductivity type impurity in the contact layer is higher than a concentration of a first conductivity type impurity in the high resistance layer.

20. The device according to claim 18, wherein the high resistance layer contains a second conductivity type impurity.
